(19) United States
(12) Patent Application Publication
(10) Pub. No.: US 2004/0114338 A1
(43) Pub. Date: Jun. 17, 2004

(54) Direct connection to a circuit board

(76) Inventors: Raymond J. Blasko, Boardman, OH (US); Mark Wayne Smith, Cortland, OH (US)

Correspondence Address: THOMAS N. TWOMEY, DELPHI TECHNOLOGIES, INC., Legal Staff, Mail Code: 480-410-202, P.O. Box 5052, Troy, MI, 48007-5052, US

(21) Appl. No.: 10/321,991

(22) Filed: Dec. 17, 2002

(51) Int. Cl. H05K 7/02

(52) U.S. Cl. 361/777

(57) ABSTRACT

An electrical connection system is provided that includes a circuit board having a substrate layer with a projection. Electrically conductive contact pads are disposed on each side of the projection and electrically connected together by a plated through hole. An electrical connection system is provided including the circuit board and a high current terminal.

### INCORPORATION BY REFERENCE

U.S. Pat. No. 6,221,514, to Hawes, et al., which is assigned to the assignee of the present invention, is hereby incorporated by reference herein in order that solder alloys need not be described in detail herein.

### TECHNICAL FIELD

The present invention relates to a circuit board having a protrusion for electrical connection to a female terminal.

### BACKGROUND OF THE INVENTION

A bussed electrical distribution center (hereinafter referred to simply as a “BEDC”) is a stand-alone central junction block assembly which has gained increasing application as electrical applications become ever more electronically sophisticated. A BEDC packages, for example, various fuses, relays and electronic devices in a single central location. Some applications call for the BEDC to distribute high current (e.g., 100-150 Amps) to devices such as an alternator on a vehicle. In some bussed electrical distribution centers known in the art, stamped metal bussed circuits are typically used to provide a connection point for a power input circuit (such as a battery) and other high current circuits. These stamped metal circuits also distribute a battery power circuit throughout an electrical center. Most connections to these stamped metal circuits comprise a ring terminal on the wiring lead with a bolted joint to the stamped metal circuit. Some of these connections comprise a female box terminal on the lead that plugs to a male blade formed from the stamped metal circuit. In either case, these stamped metal circuits add mass, package size, and cost to the electrical center.

In other bussed electrical distribution centers, high current bussing comprises a metal stamping insert molded or sandwiched between two isolating plates. The buss is then powered by a leaded ring terminated from a battery, or powered through a harness connection. The metal stampings are arranged so that the high current can be bussed to fuses and relays or out harness connections to switch other powered devices. These single-piece stampings have male blades formed up or down as required.

However, there are drawbacks to this prior technology. First, the tooling that makes the part is very expensive and changes are costly. Second, the dimensional tolerances for the formed terminals are often hard to control. Third, the formed stampings are hard to handle when placed in a mold and are easily tangled during shipping and processing.

U.S. Pat. No. 6,062,916, to Gladd, et al, describes a printed circuit board connection for an electrical distribution center. Gladd utilizes terminals that are inserted into slots or holes in the printed circuit board. Gladd is capable of distributing high current from a power source. However, initial manufacturing costs are incurred for terminals and the associated assembly to the circuit board that is required in the Gladd design.

### SUMMARY OF THE INVENTION

The present invention provides alternatives and advantages over the prior art in that it comprises a printed circuit board with a portion of the substrate functioning as a blade for a pluggable high current terminal on a wiring lead. An exposed circuit trace on the printed circuit board forms a contact pad for electrical contact with the terminal. Circuit traces are provided with suitable thickness, width, and materials to carry the required current and dissipate heat. A terminal is provided for engaging the blade. The terminal is capable of carrying high current, such as the current required by an alternator in a vehicle.

A connection system of the present invention comprises a terminal which makes contact over a relatively large surface area of the exposed circuit trace. This increases the current carrying capability of the connection. It also spreads normal forces across the surface of the exposed circuit board trace thus enabling a high current electrical connection without damaging the circuit board.

In a preferred embodiment, the connection system of the present invention comprises a two-piece terminal having a stainless steel resilient contact member. The stainless steel material maintains resiliency at high temperatures. The terminal is adapted to be ultrasonically welded to a conductive core of a wiring lead. The ultrasonically welded connection between the terminal and the conductive core provides a good interface for heat generated from a high current connection to be dissipated into the wiring lead.

The present invention can also eliminate the stamped metal circuit used in previous designs for a power input circuit to bussed electrical centers.

Finally, the direct connection to the printed circuit board eliminates the use of a threaded fastener connection that has been commonly used. This results in cost savings, reduction in mass and packaging size, and a reduction in assembly time.

### BRIEF DESCRIPTION OF THE DRAWINGS

The present invention will now be described, by way of example, with reference to the accompanying drawings, in which:

FIG. 1 is a perspective view illustrating the connection system of the present invention;

FIG. 2 is a perspective view illustrating one aspect of the present invention;

FIG. 3 is a cross-sectional view of another aspect of the present invention taken along line 3-3 of FIG. 2;

FIG. 4A is a side elevational view of another aspect of the present invention;

FIG. 4B is a cross-sectional view of another aspect of the present invention taken along lines 4B-4B of FIG. 5; and

FIG. 5 is a perspective view illustrating an aspect of the present invention.

### DETAILED DESCRIPTION OF THE INVENTION

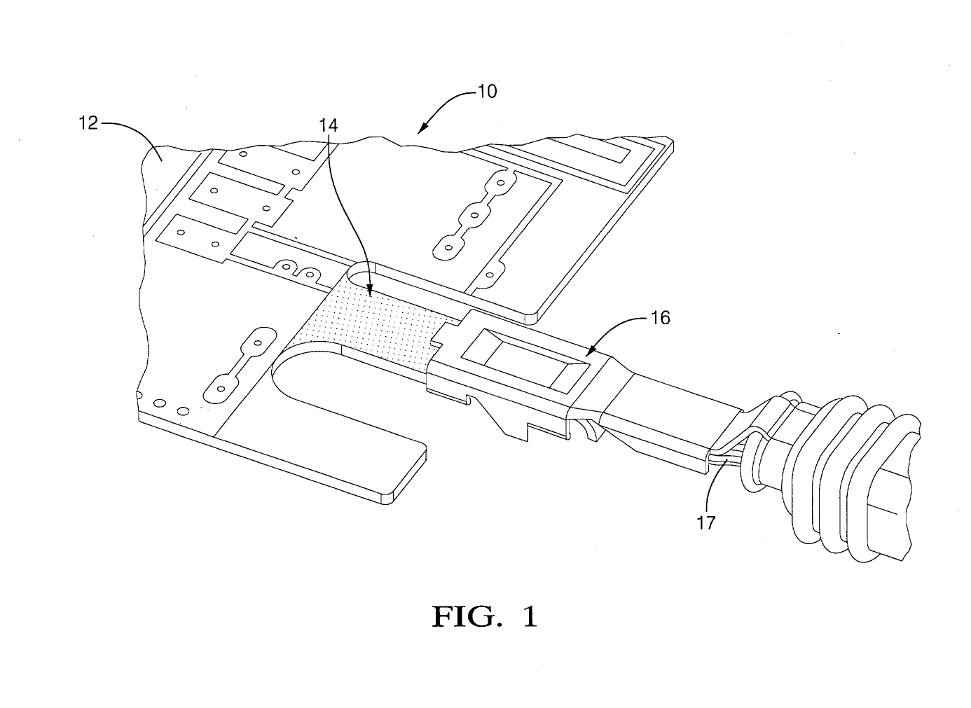

Referring to the figures wherein like numerals refer to like elements throughout the several views, FIG. 1 depicts a partially mated connection system 10 of the present invention comprising a circuit board 12 having a portion fabricated as male blade electrical termination 14 partially mated with a female terminal 16. A conductive core of a wiring lead 17 is attached to the female terminal 16. In a preferred embodiment, the conductive core of the wiring lead 17 is ultrasonically welded to the female terminal 16.

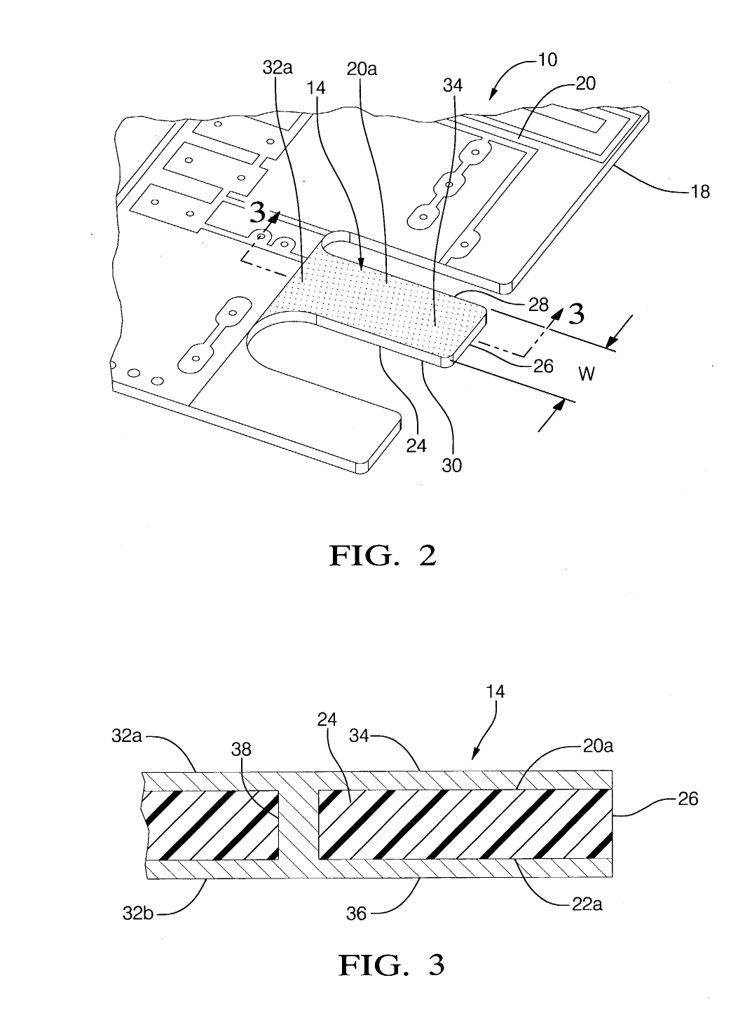

Referring to FIG. 2, the circuit board 12 comprises a substrate 18 that is preferably an electrical insulator. The substrate 18 can be of essentially any type, including ceramic, silicon, polyamide, insulated metal substrates, or laminate circuit boards, examples of which include glass-reinforced or woven fiberglass-reinforced epoxy resin laminate. The substrate 18 has a first major side 20 and a second major side (second side not shown). Alternatively, the circuit board 12 may have multiple substrate 18 layers (only one shown). The substrate 18 is fabricated having a shape that comprises a blade-like projection 24 extending co-planar with the circuit board 12. Referring to FIGS. 2 and 3, the blade-like projection 24 comprises a first and a second major side 20a, 22a, a distal edge 26, and a first and a second extending edge 28, 30. Referring to FIG. 3, an exposed portion of a conductive trace 32a, 32b on each major side 20a, 22a of the blade-like projection 24 forms an electrically conductive contact pad 34, 36 on each major side 20a, 22a. Obviously, additional distinct contact pads may be added to each major side 20a, 22a. Alternatively, the blade-like projection 24 may have a contact pad 34 on only one major side 20a. A plated through hole 38 connects the conductive traces 32a, 32b on each the two major outer sides (one side shown at 20) of the circuit board 12. Thus, the two conductive traces 32a, 32b are in electrical contact with each other. Preferably, the plated through hole 38 is located in close proximity to an area where the male blade termination 14 engages a mating part to balance current flow and temperature rise between the conductive traces 32a, 32b on each side of the two major outer sides (one side shown at 20) of the circuit board 12. The conductive traces 32a, 32b are adapted to distribute electrical current through the circuit board 12 as required by circuits and devices (not shown) connected to the circuit board 12.

The blade-like projection 24 and the contact pads 34, 36 are adapted to the shape of the male blade electrical termination 14. The male blade electrical termination 14 is adapted to engage and make electrical contact with a female terminal 16. The conductive traces 32a, 32b are preferably comprised of copper having a thickness of about 1.4 mils (1 oz. copper) to about 5.6 mils (4 oz. copper), and more preferably about 4.2 mils (3 oz. copper) to about 5.6 mils (4 oz. copper), though thicker and thinner traces and other trace compositions could be used. The contact pads 34, 36 also preferably comprise a solder coating (not shown). The solder may be a conventional solder, such as a tin-lead alloy, or a high-conductivity solder alloy such as is known in the prior art or such as disclosed in the previously cited '514 patent to Hawes, et al. A typical width W for the blade-like projection 14 is about 2 millimeters to about 15 millimeters, though the width may be less than 2 millimeters or more than 15 millimeters depending on the particular constraints of the circuit board 12 and the female terminal 16.

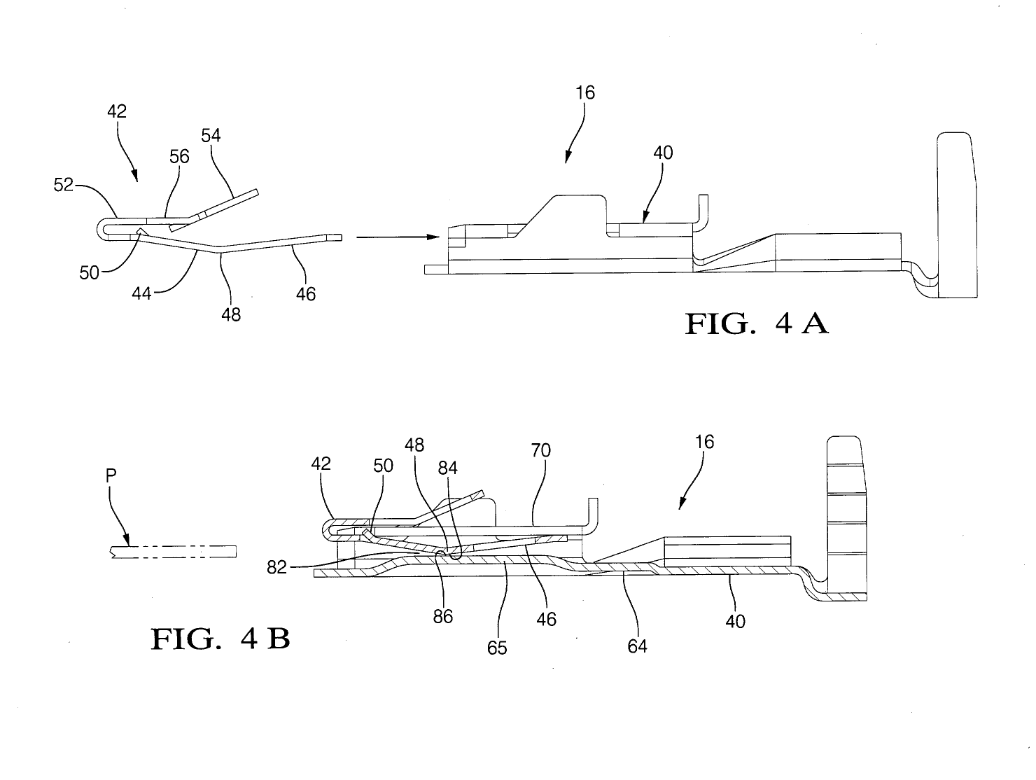

Referring to FIG. 4A, a preferred female terminal 16 is a two-piece assembly comprised of a base terminal 40 and a resilient spring member 42. The base terminal 40 is made from a sheet of an electrically conductive material such as a tin-brass base material having a silver plating over a nickel plating. hi a preferred embodiment, the electrically conductive material is suitable for ultrasonic welding to a conductive core of a cable. The spring member 42 is comprised of stainless steel. Obviously, other materials and platings known to those skilled in the art may be used.

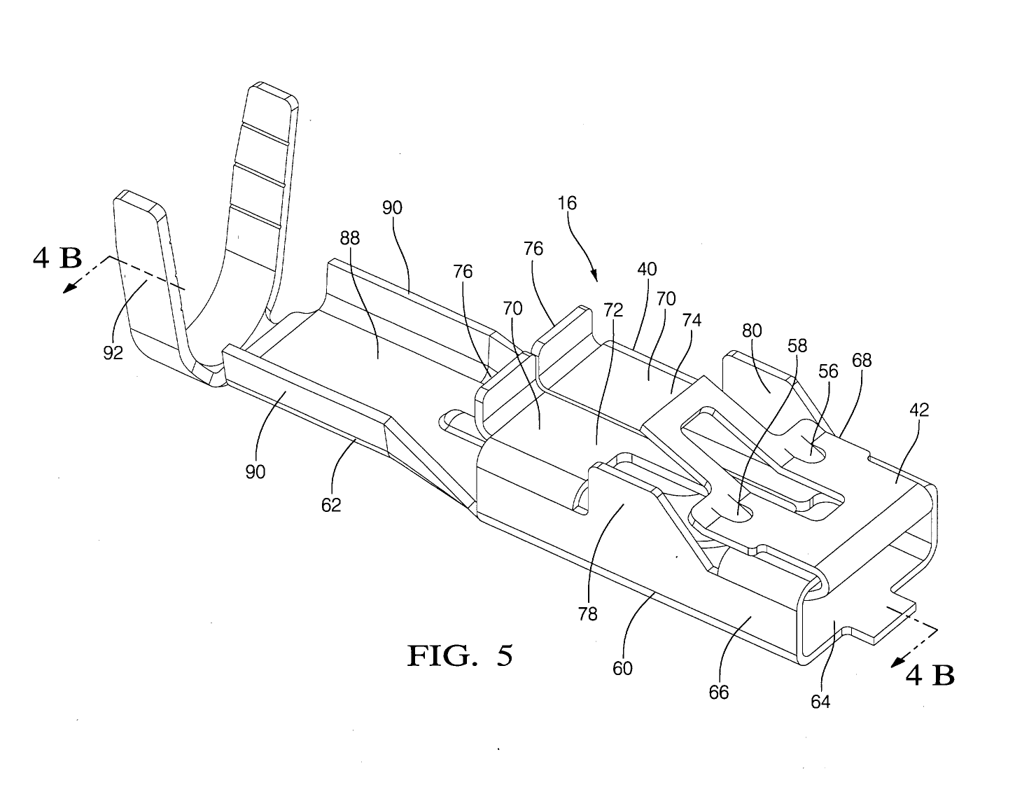

The spring member 42 is stamped and bent from a sheet of hard tempered stainless steel strip into a generally U-shaped configuration. The spring member 42 includes a lower portion 44 having a single spring finger 46 bent into a shallow V-shape having a bottom 48. An upward angled lanced tab 50 extends from the lower portion 44. The spring member 42 also comprises an upper portion 52 having an upward angled primary lock 54 and two downward angled lanced tabs 56, 58 (58 is shown on FIG. 5).

Referring now to FIG. 5, the base terminal 40 has a forward, generally box shaped, main body portion 60 and a rearward conductor engaging portion 62. The main body portion 60 includes a bottom wall 64 having a raised flat contact platform 65 (shown on FIG. 4B), first and second spaced side walls 66, 68 extending from the bottom wall 64, a top wall 70 defined by a left front ceiling portion 72 extending from the first side wall 66 and a right front ceiling portion 74 extending from the second side wall 68. The top wall 70 ends rearwardly at a vertically extending tab forming a secondary lock 76. Each side wall 66, 68 has a vertically extending indexing rib 78, 80. The spring member 42 is secured to the base terminal 40 by the three lanced tabs 50, 56, 58, which extend through slots (not shown) in the base terminal 52. As shown in FIG. 4B, when the spring member 42 is assembled to the base terminal 40 forming the assembled female terminal 16, the bottom 48 of the spring finger 46 is spaced from the raised flat contact platform 65 across a plane P to define a gap 82 for accommodating the male blade electrical termination 14 of the circuit board 12. A bottom surface of the spring finger 46 defines a first contact surface 84. A top surface of the raised flat contact platform 65 defines an opposing second contact surface 86.

Referring back to FIG. 5, the bottom wall 64 of the base terminal 40 extends rearwardly to the conductor engaging portion 62. The conductor engaging portion 62 further includes a welding pad area 88 and alignment walls 90 for ultrasonically welding the terminal 16 to a conductive core of a wire (not shown on FIG. 5) and insulation crimp wings 92 which are adapted to be crimped onto an insulated portion of the wire (not shown), and in a manner well known to those skilled in the art.

Alternatively, the female terminal 16 may be another terminal known in the prior art suitable for mating with a male blade. Alternate terminals may be attached to the wire conductor with a core crimp, ultrasonic weld, and/or other methods known to those skilled in the art.

This invention has been described with reference to a preferred embodiment and modifications thereto. Further modifications and alterations may occur to others upon reading and understanding the specification. It is intended to include all such modifications and alterations insofar as they come within the scope of the invention. For example, where particular materials are indicated, one skilled in the art would realize that other materials may be substituted.

Having thus described the invention, what is claimed is:

1. A circuit board comprising:
a substrate layer having a first and a second surface, said substrate layer including a projection;
a first electrically conductive trace disposed on said first surface of said substrate layer;
a second electrically conductive trace disposed on said second surface of said substrate layer;
a first electrically conductive contact pad disposed on a first surface of said projection, said first electrically conductive contact pad being electrically connected to said first electrically conductive trace;
a second electrically conductive contact pad disposed on a second surface of said projection, said second electrically conductive contact pad being electrically connected to said second electrically conductive trace; and
an electrical conductor connecting said first electrically conductive contact pad with said second electrically conductive contact pad.

2. The circuit board of claim 1 wherein said electrical conductor connecting said first electrically conductive contact pad with said second electrically conductive contact pad extends through said substrate layer.

3. The circuit board of claim 2 wherein a layer of solder is disposed on each of said first and second electrically conductive contact pads.

4. The circuit board of claim 3 wherein said electrical conductor extending through said substrate layer electrically connecting said first electrically conductive contact pad with said second electrically conductive contact pad comprises a plated through hole.

5. The circuit board of claim 1 wherein each of said first and second electrically conductive traces has a thickness of at least about 1.4 mils.

6. The circuit board of claim 1 wherein at least one of said first and second electrically conductive traces has a thickness of at least about 4.2 mils.

7. The circuit board of claim 1 wherein at least one of said first and second electrically conductive traces has a thickness of about 4.2 mils to about 5.6 mils.

8. The circuit board of claim 1 wherein each of said first and second electrically conductive traces has a thickness of at least about 4.2 mils.

9. A circuit board comprising:
a substrate having a first and a second surface, said substrate including a projection for electrical connection with a female terminal;
a first electrically conductive trace disposed on said first surface of said substrate, said first electrically conductive trace having a thickness of at least 4.2 mils; and
a first electrically conductive contact pad disposed on a first surface of said projection, said first electrically conductive contact pad being electrically connected to said first electrically conductive trace.

10. The circuit board of claim 9 further comprising:
a second electrically conductive contact pad disposed on a second surface of said projection; and
an electrical conductor connecting said first electrically conductive contact pad with said second electrically conductive contact pad.

11. The circuit board of claim 10 wherein said electrical conductor connecting said first electrically conductive contact pad with said second electrically conductive contact pad comprises a plated through hole extending through said substrate.

12. The circuit board of claim 11 wherein a layer of solder is disposed on each of said first and second electrically conductive contact pads.

13. An electrical connection system comprising:
a circuit board comprising a substrate layer having a first and a second surface, said substrate layer including a projection, a first electrically conductive trace disposed on said first surface of said substrate layer, a second electrically conductive trace disposed on said second surface of said substrate layer, a first electrically conductive contact pad disposed on a first surface of said projection, said first electrically conductive contact pad being electrically connected to said first electrically conductive trace, a second electrically conductive contact pad disposed on a second surface of said projection, and an electrical conductor connecting said first electrically conductive contact pad with said second electrically conductive contact pad; and
a terminal receiving said projection and making electrical contact with said first and second electrically conductive contact pads, said terminal comprising a base terminal member made of an electrically conductive material, said base terminal member having a forward main body portion and conductor engaging means extending rearwardly from said main body portion.

14. The electrical connection system of claim 13 wherein said main body portion has a bottom wall, first and second spaced side walls, and a top wall, said bottom wall having a raised contact platform for contacting one of said first and said second contact pads, said walls defining an opening at a forward end of said base terminal member.

15. The electrical connection system of claim 14 further comprising a spring member being attached to said top wall, said spring member having a surface for contacting one of said first and said second contact pads.

16. The electrical connection system of claim 13 wherein said conductor engaging means comprise a welding pad area and insulation crimp wings.

17. The electrical connection system of claim 16 further comprising an electrically conductive wire, said electrically conductive wire being ultrasonically welded to said welding pad area of said terminal.

18. The electrical connection system of claim 13 wherein at least one of said first and second electrically conductive traces has a thickness of at least about 1.4 mils.

19. The electrical connection system of claim 13 wherein at least one of said first and second electrically conductive traces has a thickness of at least about 4.2 mils.

20. The electrical connection system of claim 13 wherein at least one of said first and second electrically conductive traces has a thickness about 1.4 mils to about 5.6 mils.
